(19) United States
(12) Patent Application Publication
(10) Pub. No.: US 2003/0087488 A1
(43) Pub. Date: May 8, 2003

(54) Inductively coupled plasma source for improved process uniformity

(75) Inventors: Steven T. Fink, Mesa, AZ (US); Janusz Sosnowski, Chandler, AZ (US)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 10/289,389

(22) Filed: Nov. 7, 2002

Related U.S. Application Data
(60) Provisional application No. 60/331,033, filed on Nov. 7, 2001.

(51) Int. Cl. H01L 21/8238

(52) U.S. Cl. 438/200

(57) ABSTRACT

An improved apparatus for material processing, wherein the improved apparatus including a plasma processing system to process a substrate, the plasma processing system including a process chamber, a substrate holder, and a plasma source. The plasma source further includes an inductive coil assembly for inductively coupling RF power to plasma wherein the inductive coil assembly is arranged within a process chamber. The inductive coil assembly includes an inner conductor, a slotted outer conductor, and a dielectric layer. The inductive coil assembly can further include a second dielectric layer in order to protect the slotted outer conductor from plasma. The inner conductor is surrounded by the slotted outer conductor and, between which, resides the first dielectric layer. The second dielectric layer encapsulates the inner conductor, first dielectric layer and the slotted outer conductor.

### CROSS-REFERENCE TO RELATED APPLICATION

This application claims priority to United States provisional serial no. 60/331,033, filed on Nov. 7, 2001, the entire contents of which are herein incorporated by reference.

### BACKGROUND OF THE INVENTION

1. Field of Invention

The present invention relates to inductively coupled plasma sources and more particularly to inductively coupled plasma sources for improved process uniformity.

2. Description of Related Art

Plasma processing systems are used in the manufacture and processing of semiconductors, integrated circuits, displays and other devices or materials, to both remove material from or to deposit material on a substrate such as a semiconductor substrate.

Increasing miniaturization of technology increases the demand for improved resolution in design features with increasing complexity and higher aspect ratios. In order to achieve these, improved process uniformity can be beneficial. In plasma processing systems, one factor affecting the degree of etch or deposition uniformity is the spatial uniformity of the plasma density above the substrate.

In spite of significant advances, most etch processes still induce a non-uniform and undesirable etch profile. Non-uniformity can be caused by a non-symmetrical exhaust flow, temperature variations, non-uniform plasma chemistry, non-uniform ion density or non-uniform gas supply. These factors can cause variations in the etch rate, selectivity and sidewall profiles in device features on a wafer.

In addition, conventional plasma processing devices utilize plasma sources comprising a significant number of complex components leading to excessive fabrication times, fabrication costs and problems with the consistency of the plasma source assembly. Therefore, a reduction of the number of parts in any machine reduces the complexity and lowers the overall cost of the machine, hence, lowering the cost to process each wafer.

Furthermore, maintaining a semiconductor-processing machine is time consuming and an expensive procedure. Removing and servicing parts above the wafer that produce plasma cause machine downtimes that add to the overall cost to process each wafer. Conventional plasma processing devices are not amenable to quick and efficient maintenance and service of plasma sources and, therefore, machine down-time can be significant.

### SUMMARY OF THE INVENTION

The present invention provides for an improved apparatus for material processing, wherein the improved apparatus comprises a plasma processing system to process a substrate, the plasma processing system comprising a process chamber, a substrate holder, and a plasma source. The plasma source further comprises an inductive coil assembly for inductively coupling RF power to plasma wherein the inductive coil assembly is arranged within the process chamber.

It is a first object of the present invention to provide an inductive coil assembly configured to be arranged within the process chamber. The inductive coil assembly comprises an inner conductor, a slotted outer conductor, and a dielectric layer. The inner conductor is surrounded by the slotted outer conductor and, between which, resides the first dielectric layer.

It is a further object of the present invention to encapsulate the slotted outer conductor within a second dielectric layer in order to protect the outer conductor from plasma.

It is a further object of the present invention to provide an inductive coil assembly for coupling RF power to plasma wherein the inductive coil assembly additionally comprises an impedance match network.

### BRIEF DESCRIPTION OF THE DRAWINGS

These and other objects and advantages of the invention will become more apparent and more readily appreciated from the following detailed description of the exemplary embodiments of the invention taken in conjunction with the accompanying drawings, where:

FIG. 1 shows a plasma processing system according to a first embodiment of the present invention;

FIG. 2 shows an inductive coil assembly according to an embodiment of the present invention;

FIG. 3 shows an inductive coil assembly according to an embodiment of the present invention;

FIG. 4A presents a schematic cross-section of an inductive coil assembly according to an embodiment of the present invention;

FIG. 4B presents a schematic plan view of an inductive coil assembly corresponding to the schematic of FIG. 4A;

FIG. 5A shows a section of a slotted inductive coil according to an embodiment of the present invention;

FIG. 5B shows a section of a slotted inductive coil according to an embodiment of the present invention;

FIG. 5C shows a section of a slotted inductive coil according to an embodiment of the present invention;

FIG. 6 shows a plasma processing system according to a second embodiment of the present invention;

FIG. 7A shows a side view of a plasma processing system according to a third embodiment of the present invention;

FIG. 7B shows a top view of a plasma processing system according to a third embodiment of the present invention; and

FIG. 8 presents an impedance match network according to an embodiment of the present invention.

### DETAILED DESCRIPTION OF EXEMPLARY EMBODIMENTS

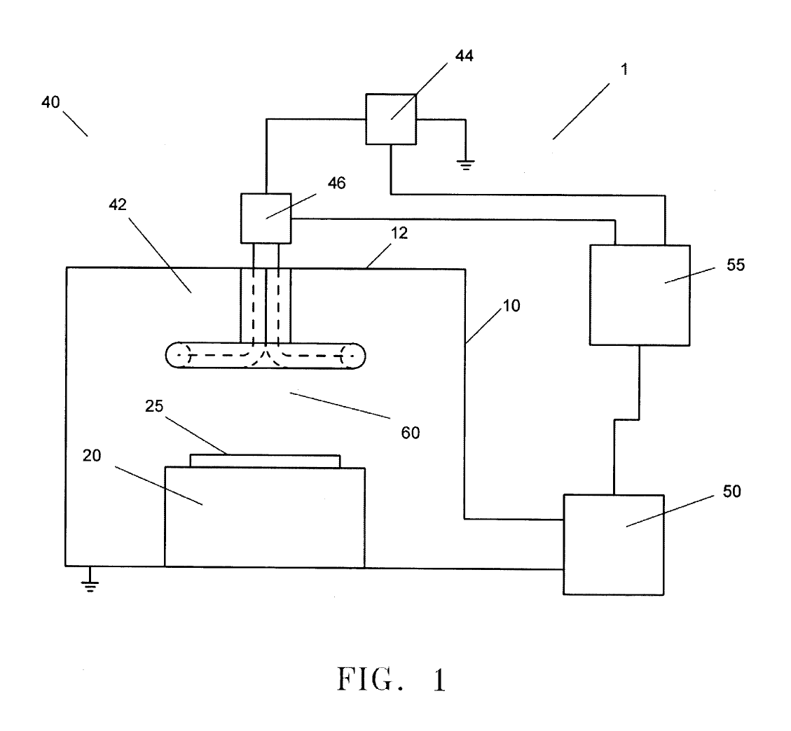

A plasma processing device 1 is depicted in FIG. 1 including chamber 10, substrate holder 20, upon which a substrate 25 to be processed is affixed, plasma source 40, and vacuum pumping system 50. Chamber 10 is configured to facilitate the generation of plasma in processing region 60 adjacent a surface of substrate 25, wherein plasma is formed via collisions between heated electrons and an ionizable gas. An ionizable gas or mixture of gases is introduced to chamber 10 and the process pressure is adjusted. For example, a gate valve (not shown) can be used to throttle the vacuum pumping system 50. Desirably, plasma is utilized to create materials specific to a predetermined materials process, and to aid either the deposition of material to substrate 25 or the removal of material from the exposed surfaces of substrate 25.

Substrate 25 is transferred into and out of chamber 10 through a slot valve (not shown) and chamber feed-through (not shown) via robotic substrate transfer system where it is received by substrate lift pins (not shown) housed within substrate holder 20 and mechanically translated by devices housed therein. Once substrate 25 is received from substrate transfer system, it is lowered to an upper surface of substrate holder 20.

In an alternate embodiment, the substrate 25 is affixed to the substrate holder 20 via an electrostatic clamping system (not shown). Furthermore, substrate holder 20 can further include a cooling system including a re-circulating coolant flow that receives heat from substrate holder 20 and transfers heat to a heat exchanger system (not shown), or when heating, transfers heat from the heat exchanger system. Moreover, gas can be delivered to the back-side of the substrate via a backside gas system (not shown) to improve the gas-gap thermal conductance between substrate 25 and substrate holder 20. Such a system can be utilized when temperature control of the substrate is required at elevated or reduced temperatures. For example, temperature control of the substrate can be useful at temperatures in excess of the steady-state temperature achieved due to a balance of the heat flux delivered to the substrate 25 from the plasma and the heat flux removed from substrate 25 by conduction to the substrate holder 20. In other embodiments, heating elements, such as resistive heating elements, or thermoelectric heaters/coolers can be included.

Referring still to FIG. 1, substrate holder 20 further serves as an electrode through which RF power is coupled to plasma in processing region 60. For example, substrate holder 20 can be electrically biased at a RF voltage via the transmission of RF power from a RF generator (not shown) through an impedance match network (not shown) to substrate holder 20. The RF bias can serve to provide a DC self-bias on substrate 25 and, thereby, attract ions to the upper surface of substrate 25. The bias power can be varied in order to affect changes in the arriving ion energy and thus affect changes in the nature of the material process at the surface of substrate 25. A typical frequency for the RF bias can range from 1 MHz to 100 MHz and is preferably 13.56 MHz. RF systems for plasma processing are well known to those skilled in the art.

Vacuum pump system 50 preferably includes a turbo-molecular vacuum pump (TMP) capable of a pumping speed up to 5000 liters per second (and greater) and a gate valve for throttling the chamber pressure. In conventional plasma processing devices utilized for dry plasma etch, a 1000 to 3000 liter per second TMP is employed. TMPs are useful for low pressure processing, typically less than 50 mTorr. At higher pressures, the TMP pumping speed falls off dramatically. For high pressure processing (i.e. greater than 100 mTorr), a mechanical booster pump and dry roughing pump can be used.

Controller 55 comprises a microprocessor, memory, and a digital I/O port capable of generating control voltages sufficient to communicate and activate inputs to plasma processing system 1 as well as monitor outputs from plasma processing system 1. Moreover, controller 55 is coupled to and exchanges information with RF generator 44, impedance match network 46, and vacuum pump system 50. A program stored in the memory is utilized to activate the inputs to the aforementioned components of a plasma processing system 1 according to a stored process recipe. One example of controller 55 is a DELL PRECISION WORKSTATION 610TM, available from Dell Corporation, Dallas, Tex. In an alternate embodiment, controller 55 is a digital signal processor (DSP).

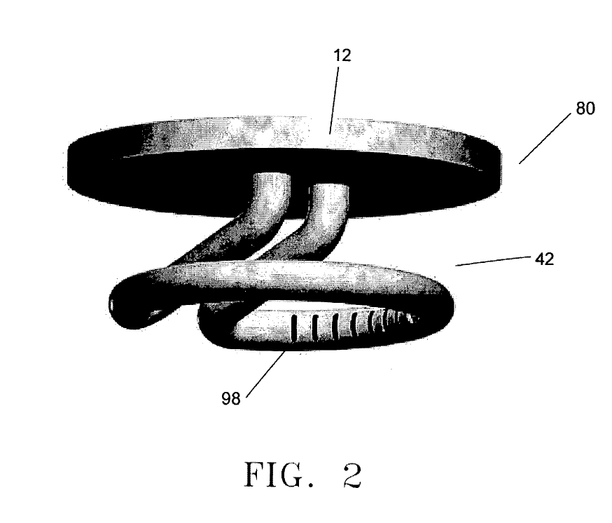

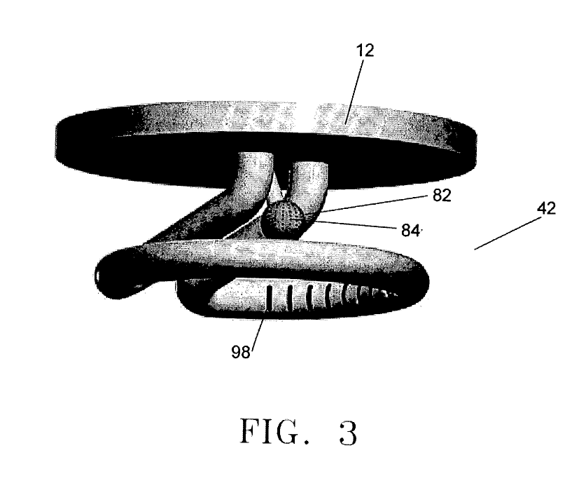

With continuing reference to FIG. 1, process gas is introduced to processing region 60 through a gas injection system to be described below. Process gas can, for example, comprise a mixture of gases such as argon, CF4 and O2, or argon, C4F8 and O2 for oxide etch applications. In an embodiment of the present invention as shown in FIG. 2, process gas can be introduced to plasma region 60 through an upper wall 12 of chamber 10 via a gas injection manifold 80. Gas injection manifold 80 can, for example, comprise a showerhead gas injection system, wherein process gas is supplied from a gas delivery system (not shown) to the plasma region 60 through a gas injection plenum (not shown), a series of baffle plates (not shown) and a multi-orifice showerhead gas injection plate (not shown). The above description of showerhead gas injection systems is well known to those of skill in the art. In an alternate embodiment of the present invention as shown in FIG. 3, process gas can be introduced to plasma region 60 from a gas injection manifold 82 that is coupled to the upper wall 12 of chamber 10. Gas injection manifold 82 can comprise a spherical injection head upon which are a plurality gas injection orifices 84. As appreciated by those skilled in the art, process gas can be introduced to plasma region from any of the surfaces forming chamber 10 and in other locations relative to the position of inductive coil assembly 42.

Referring again to FIG. 1, plasma source 40 comprises an inductive coil assembly 42 for coupling RF power to plasma region 60. As shown in FIGS. 1, 2 and 3, inductive coil assembly 42 is arranged within the process chamber 10 and extends into plasma region 60 from upper wall 12 of chamber 10. It can be, for example, positioned substantially above substrate 25. The inductive coil assembly 42, in general, comprises a single loop antenna disposed substantially parallel to substrate 25 as shown in cross-section in FIG. 1. RF power is coupled to the inductive coil assembly 42 via RF generator 44 through an impedance match network 46.

Furthermore, still referring to FIGS. 1, 2 and 3, the method of providing an inductive coil assembly appended to the upper wall 12 of process chamber 10 allows for expedient replacement of the inductive coil assembly 42 simply by removing the upper wall 12 (or lid) of process chamber 10.

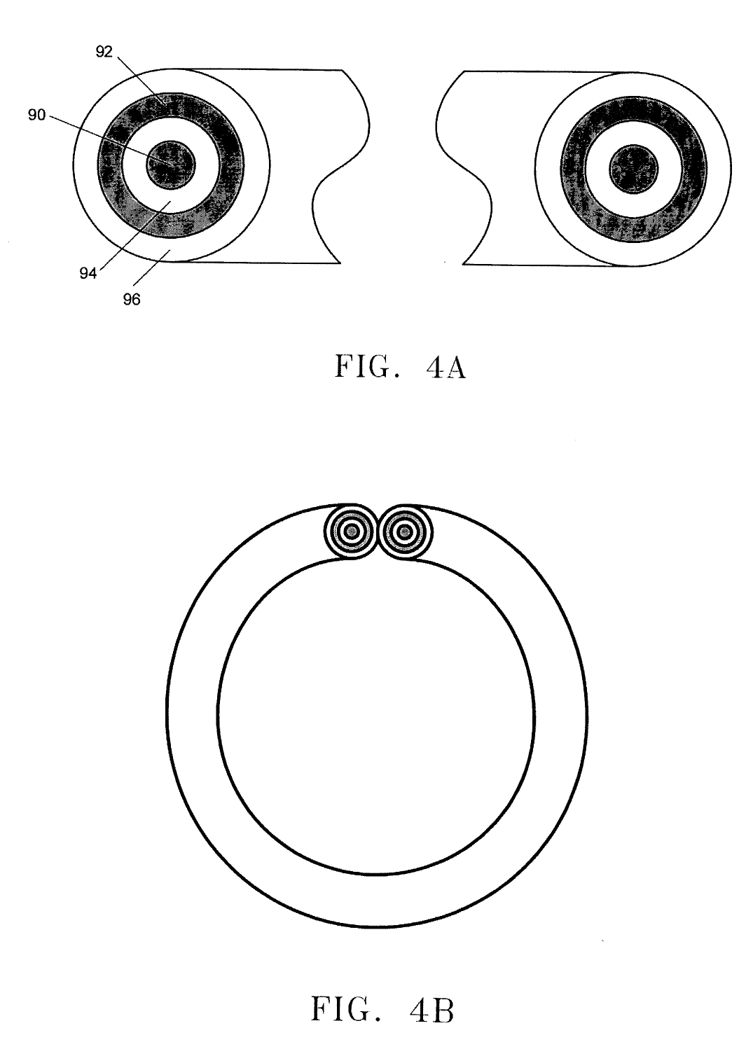

FIGS. 4A and 4B present in greater detail a cross-section and top view, respectively, of the inductive coil assembly 42. The inductive coil assembly comprises an inner conductor 90 and a slotted outer conductor 92, between which resides a dielectric layer 94. In an alternate embodiment, the slotted outer conductor 92 can be further encapsulated within a second dielectric layer 96, wherein the second dielectric layer 96 serves to protect the slotted outer conductor 92 from the plasma. The inner conductor 90 and slotted outer conductor 92 are fabricated from conducting materials such as, for example, copper, aluminum, etc. and can be, for example, constructed from copper tubing. Dielectric layer 94 and second dielectric layer 96 can be, for example, any one of air, vacuum, Teflon (PTFE), alumina, quartz, polyimide, etc.

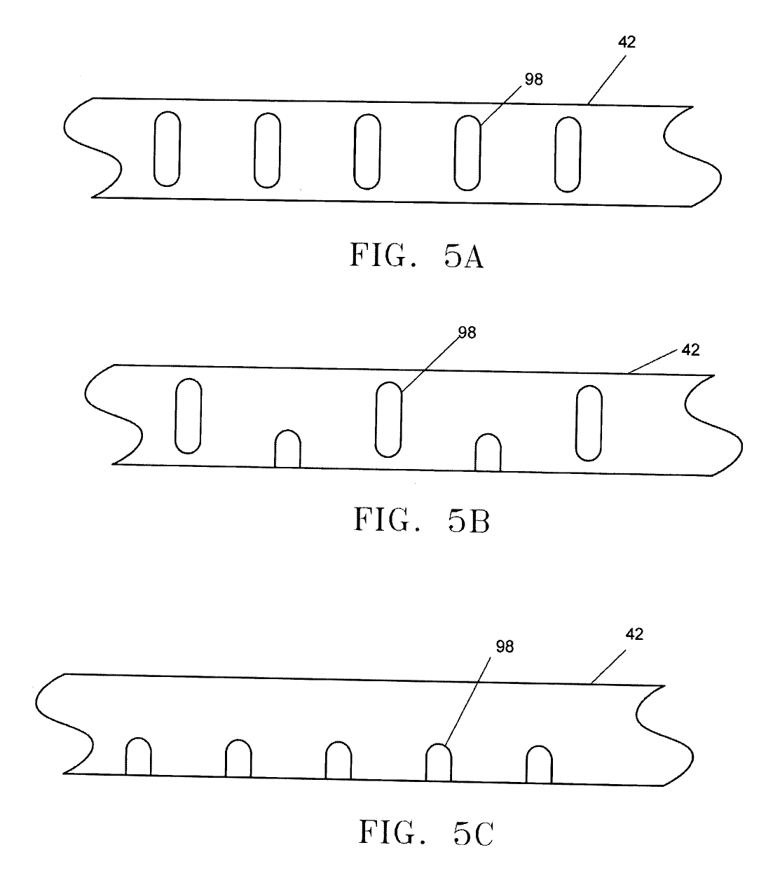

Furthermore, as shown in FIGS. 2 and 3, slots 98 are formed within the slotted outer conductor 92. In an alternate embodiment, slots 98 are formed prior to application of the second dielectric layer 96. The slots 98 permit inductively coupling power from the inner conductor 90 to the plasma region 60 while minimizing capacitive coupling between the inner conductor 90 and the plasma region 60. The slotted outer conductor 92 with slots 98 acts as a grounded, electrostatic shield (or Faraday shield). FIGS. 5A, 5B and 5C present three orientations for the slots 98 in the slotted outer conductor 92. In FIG. 5A, the slots 98 are oriented vertically and directed in a radial direction (either inwardly or outwardly) substantially parallel with substrate 25. In FIG. 5B, every other slot 98 is directed in a radial direction substantially parallel with substrate 25 whereas the remaining slots are directed in a radial direction substantially normal to substrate 25. In FIG. SC, all of the slots 98 are directed in a radial direction substantially normal to substrate 25. Although several configurations are described in FIGS. 5A, 5B and 5C, the orientation of slots 98, the direction of each slot 98, the width and length of each slot 98 and the number of slots 98 can be varied. The design of an electrostatic shield is well known to those skilled in the art.

In an alternate embodiment, the inductive coil assembly 42 comprises a multi-turn antenna as opposed to a single-turn antenna as shown in FIGS. 1 through 3.

In an embodiment of the present invention, the inductive coil assembly 42 can be formed from, for example, a stripped coaxial RF cable which is inserted within, for example, a pre-formed copper tube, wherein the stripped coaxial RF cable provides the inner conductor 90 and the dielectric layer 94, and the copper tubing forms the slotted outer conductor 92. Thereafter, the inductive coil assembly 42 can be spray coated with, for example, alumina using processes well known to those skilled in the art of spray coatings to form the second dielectric layer 96.

Due to the potential for heating the inductive coil assembly 42 particularly when immersed within plasma, it can be necessary to provide internal cooling. Internal cooling of the inductive coil assembly 42 can be achieved either by micro-machining channels within the dielectric layer 94 and flowing a dielectric fluid, such as, for example, Fluorinert, through the micro-channels from the input end of the inductive coil assembly 42 to the output end of the inductive coil assembly 42, or by flowing a coolant, such as, for example, water, internally within the inner conductor from the input end of the inductive coil assembly 42 to the output end of the inductive coil assembly 42.

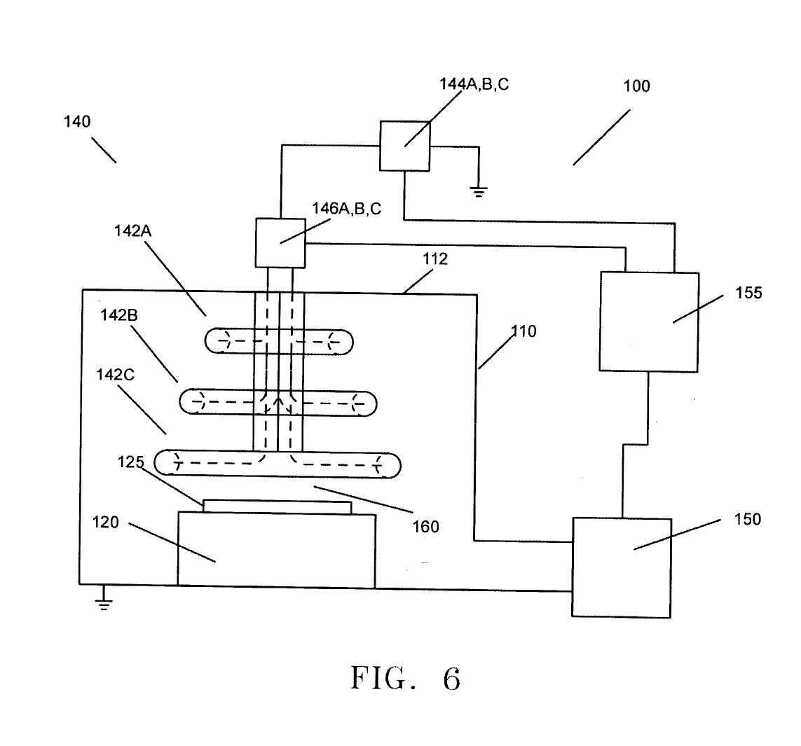

Referring now to FIG. 6, a second embodiment of the present invention is shown. A plasma processing system comprises a chamber 110 and a plasma source 140, wherein plasma source 140 further includes a plurality of inductive coil assemblies 142A, 142B and 142C. RF power is coupled to each inductive coil assembly 142(A-C) via RF generators 144 (A-C) through respective impedance match networks 146 (A-C). A controller 155 is coupled to each RF generator 142 (A-C), each impedance match network 146 (A-C) and vacuum pumping system 150. The inductive coil assemblies 142A, 142B and 142C are arranged within the process chamber 110 and can extend to different distances from upper wall 112 of chamber 110 into plasma region 160 as shown in FIG. 6, or they can extend to the same distance from upper wall 112. A plurality of inductive coil assemblies 142 (A-C), as exemplified in FIG. 6, can enable adjustment of the plasma uniformity local to substrate 25. The coils include concentric shapes (e.g., rings) that are the same height above the wafer, or, alternatively, as shown, concentric shapes (e.g., rings) that are a varying distance above the wafer. The distances of the coils can be variable (e.g., where the outermost concentric ring is the greatest distance from the wafer and the innermost concentric ring is the closest to the wafer or vice versa).

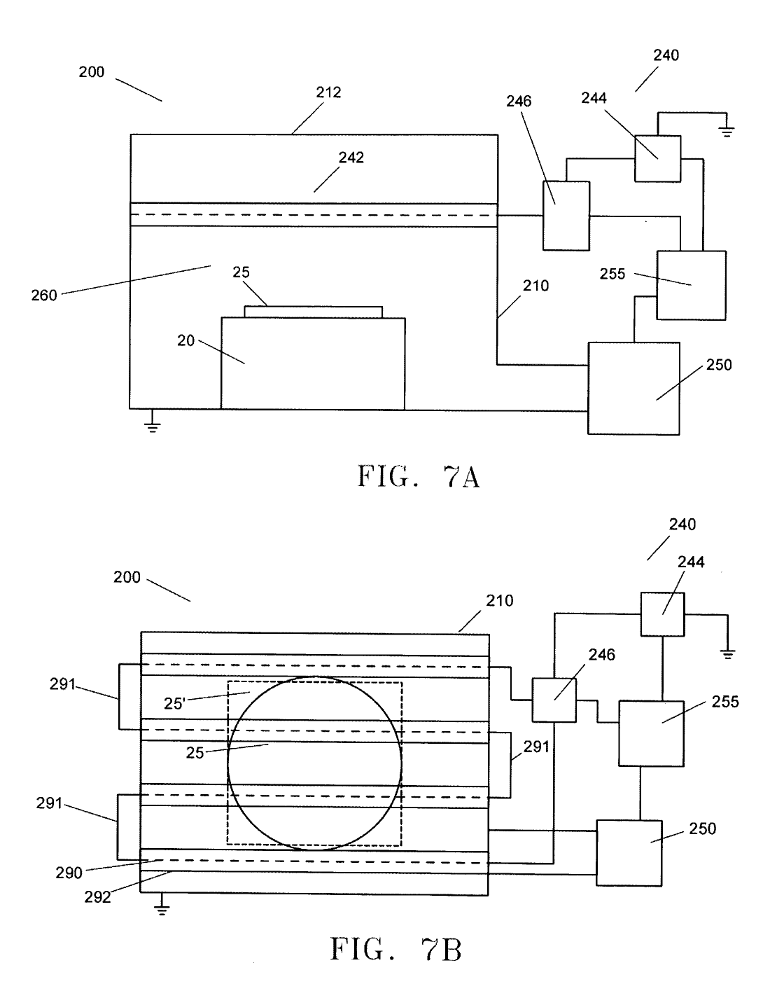

Referring now to FIGS. 7A (side view) and 7B (top view), a third embodiment of the present invention is shown. A plasma processing system 200 comprises a chamber 210 and a plasma source 240, wherein plasma source 240 further includes a linear inductive coil assembly 242. RF power is coupled to linear inductive coil assembly 242 via RF generator 244 through an impedance match network 246. The linear inductive coil assembly 242 is arranged within the process chamber 210 and can be positioned a finite distance below upper wall 212 of chamber 210 above substrate 25 as shown in FIG. 7A. Furthermore, the linear inductive coil assembly 242 can extend across chamber 210 in a transverse direction making several passes above substrate 25 (25′) as shown in FIG. 7B. For example, in FIG. 7B, four (4) passes across chamber 210 are made with inductive coil assembly 242. The linear inductive coil assembly 242 further comprises an inner conductor 290 surrounded by a slotted outer conductor 292, between which is inserted a dielectric layer 294. In an alternate embodiment, the slotted outer conductor 292 can be encapsulated within a second dielectric layer 296 in order to protect the slotted outer conductor 292 from plasma. The slotted outer conductor 292 is mechanically and electrically coupled to the grounded chamber 210. Moreover, as shown in FIG. 7B, electrical elements 291 electrically couple ends of inner conductor 290 to provide continuity of the electrical circuit. In a linear configuration, the plasma source 240 can be configured to process either a circular substrate 25 (e.g. semiconductor wafer) or a non-circular substrate 25′ (e.g. rectangular liquid crystal display, LCD).

Although not shown in FIGS. 7A and 7B, linear inductive coil assembly 242 further comprises slots in the outer conductor 292 in order for the outer conductor 292 to act as an electrostatic shield.

In an embodiment of the present invention, the linear inductive coil assembly 242 can be formed from concentric copper tubes wherein the first copper tube of lesser radius acts as the inner conductor 290 and the outer copper tube of greater radius acts as the slotted outer conductor 292. Slots 298 can be pre-machined within the outer conductor 292 and a pre-machined concentric Teflon rod can be fit between the inner and slotted outer conductors, 290 and 292, respectively. Moreover, the slotted outer conductor 292 can be inserted within a dielectric tube such as, for example, a quartz tube, which serves as the second dielectric layer 296. In an alternate embodiment, the inductive coil assembly 242 can be spray coated with, for example, alumina to form the second dielectric layer 296.

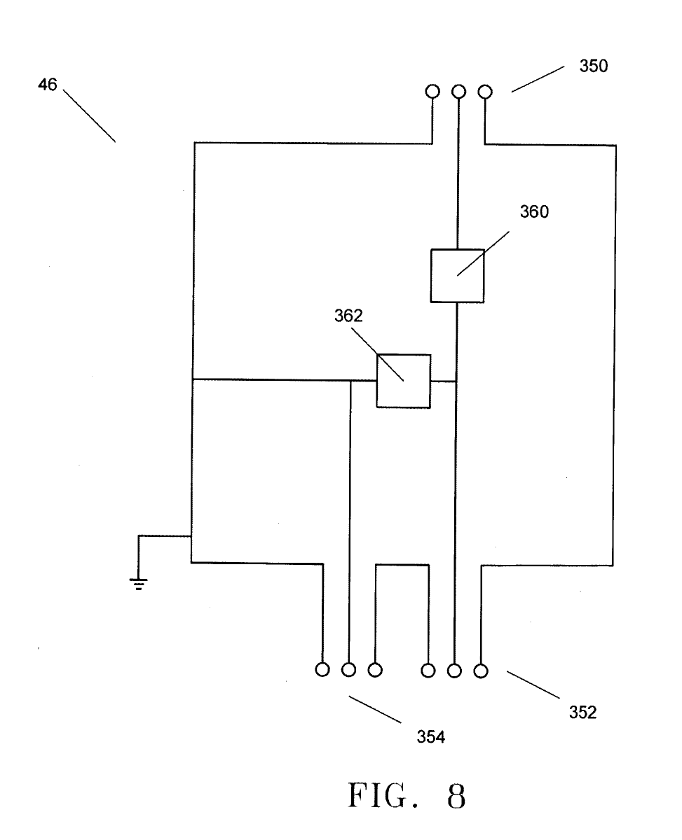

Referring now to FIG. 8, an impedance match network 46, comprising a first RF connection 350 coupled to the output of RF generator 44, a second RF connection 352 coupled to the input end of inductive coil assembly 42 and a third RF connection 354 coupled to an output end of inductive coil assembly 42, can be utilized to maximize power transfer from RF generator 44 to plasma region 60. The impedance match network 46 can be, for example, designed for a T-type topology including a first variable capacitor 360 and a second variable capacitor 362. Actuation of variable capacitors and methods in automatic control of impedance match networks are well known to those skilled in the art of RF circuitry. For further details, pending U.S. patent application serial No. 60/277,965 (filed on Mar. 23, 2001) is incorporated herein by reference in its entirety.

In an alternate embodiment, RF power is coupled to the inductive coil at multiple frequencies. Furthermore, impedance match network 46 which serves to maximize the transfer of RF power to plasma region 60 in processing chamber 10 by minimizing the reflected power can have other topologies such as L-type and π-type. Match network topologies (e.g. L-type, π-type, etc.) and automatic control methods are well known to those skilled in the art.

Although only certain exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

1. An apparatus for material processing, the apparatus comprising
process chamber,
substrate holder, and
plasma source, said plasma source comprising at least one inductive coil assembly arranged within said process chamber, wherein said at least one inductive coil assembly comprises an inner conductor, a slotted outer conductor, and a dielectric layer.

2. The apparatus according to claim 1, wherein said at least one inductive coil assembly further comprises a second dielectric layer coupled to said outer conductor.

3. The apparatus according to claim 1, wherein said at least one inductive coil assembly is a single-turn antenna.

4. The apparatus according to claim 1, wherein said at least one inductive coil assembly is a multi-turn antenna.

5. The apparatus according to claim 1, wherein said at least one inductive coil assembly is a linear antenna.

6. The apparatus according to claim 1, wherein said inner conductor comprises at least one of copper and aluminum.

7. The apparatus according to claim 1, wherein said slotted outer conductor comprises at least one of copper and aluminum.

8. The apparatus according to claim 1, wherein said dielectric layer comprises at least one of air, vacuum, Teflon, alumina, quartz and polyimide.

9. The apparatus according to claim 2, wherein said second dielectric layer comprises at least one of air, vacuum, Teflon, alumina, quartz and polyimide.

10. The apparatus according to claim 1, wherein said at least one inductive coil assembly is substantially parallel to said substrate holder.

11. The apparatus according to claim 1, wherein said plasma source further comprises an impedance match network.

12. A plasma processing system, the apparatus comprising
process chamber,
substrate holder, and
plasma source, said plasma source comprising a plurality of inductive coil assemblies arranged within said process chamber, wherein each of said plurality of inductive coil assemblies comprises inner conductor, slotted outer conductor, and dielectric layer.

13. The apparatus according to claim 12, wherein at least one of said plurality of inductive coil assemblies further comprises a second dielectric layer coupled to said outer conductor.

14. The apparatus according to claim 12, wherein at least one of said plurality of inductive coil assemblies is a single-turn antenna.

15. The apparatus according to claim 12, wherein at least one of said plurality of inductive coil assemblies is a multi-turn antenna.

16. The apparatus according to claim 12, wherein at least one of said plurality of inductive coil assemblies is a linear antenna.

17. The apparatus according to claim 12, wherein said inner conductor comprises at least one of copper and aluminum.

18. The apparatus according to claim 12, wherein said slotted outer conductor comprises at least one of copper and aluminum.

19. The apparatus according to claim 12, wherein said dielectric layer comprises at least one of air, vacuum, Teflon, alumina, quartz and polyimide.

20. The apparatus according to claim 13, wherein said second dielectric layer comprises at least one of air, vacuum, Teflon, alumina, quartz and polyimide.

21. The apparatus according to claim 12, wherein at least one of said plurality of inductive coil assemblies is substantially parallel to said substrate holder.

22. The apparatus according to claim 12, wherein said plasma source further comprises an impedance match network.

23. A method of plasma processing a substrate, the method comprising the steps of arranging at least one inductive coil assembly in a process chamber, wherein said at least one inductive coil assembly comprises an inner conductor, a slotted outer conductor, and a dielectric layer,
arranging a substrate on a substrate holder,
supplying a process gas to said process chamber,
applying a RF power to the at least one inductive coil assembly, and
processing said substrate to completion, wherein said completion is dictated by a recipe.

24. In a method of applying RF power to a plasma processing chamber, the improvement comprising:
arranging at least one inductive coil assembly in a process chamber, wherein said at least one inductive coil assembly comprises an inner conductor, a slotted outer conductor, and a dielectric layer; and
applying a RF power to the at least one inductive coil assembly.
